(19) United States
(12) Patent Application Publication
(10) Pub. No.: US 2012/0091494 A1
(43) Pub. Date: Apr. 19, 2012

(54) COMPOSITE LUMINESCENT MATERIAL FOR SOLID-STATE SOURCES OF WHITE LIGHT

(76) Inventors: Anatoly Vasilyevich Vishnyakov, Moscow (RU); Dmitry Yuryevich Sokolov, Moskovskaya Oblast (RU); Natalia Anatolyevna vishnyakova, Moscow (RU)

(21) Appl. No.: 13/378,014

(22) PCT Filed: Dec. 4, 2009
(86) PCT No.: PCT/RU09/00669

§ 371 Date: Dec. 13, 2011

(51) Int. Cl. H01L 33/44

(52) U.S. Cl. 257/98; 257/E33.061

(57) ABSTRACT

A composite luminescent material for solid white light sources that include a light-emitting diode radiating in the 430-480 nm range and a mixture of at least two phosphors, one of which has yellow-orange luminescence in the 560-630 nm range, while the other one belongs to the group of aluminates of alkali-earth metals, activated by europium, different in that the second phosphor represents at least one light storage phosphor, virtually unexcitable by the light-emitting diode primary radiation and having a long afterglow. Cerium-activated yttrium-aluminate and/or terbium-aluminate garnets of various compositions, with the general formula (Ln)₃Al₅O₁₂, and/or cerium-activated phosphors based on a non-stoichiometric phase with the general formula

(Ln)₃Al₅O_{12+1.5α}, wherein Ln=Y, Tb, Gd, Ce, La, Lu, Pr, and/or europium-activated phosphors of the following composition: (Ca,Sr,Ba)₂Si₅N₈:Eu²⁺ can be used as a phosphors with yellow-orange luminescence. One or several aluminates of alkali-earth metals with the general formula
(Sr²⁺, Ca²⁺, Mg²⁺, Ba²⁺, Zn²⁺, Mn²⁺)_{1÷4}Al(B,Ga)_{2÷14}O_{4÷25}:Eu²⁺(Ce³⁺,Tb³⁺,Dy³⁺, Nd³⁺, Pr³⁺) can be used as light storage phosphors.

Concentration of light storage phosphors can vary within the 10-90 mass % range, the most useful range being 40 to 70 mass %. The material produced is characterized by high brightness, and its illumination engineering parameters fit the absolute black body emission curve with the colour temperature from 2,900 to 6,100 K. The new material has a long afterglow and is inexpensive.

This invention relates to lighting engineering, in particular to luminescent materials used in solid sources of white light, which produce white luminescence as a result of a combination of the yellow-orange luminescence of the phosphor, based on yttrium-gadolinium garnet, with blue light (430-480 nm) generated by an InGaN light-emitting diode (LED).

Two types of LED sources of white light are known. Formally, they can be classified as quasi-point light sources (white LED lamps) and spatial light transforming systems. In the former case, a yellow-orange phosphor, dispersed in an optically transparent photo- and thermo-resistant polymer, is located either in direct contact with a light-emitting diode or is rather close to the last one. In devices of the other type, called bulb white LED lamps, the light emitting diode and phosphor are spatial separated. The blue light transmits through the shell of a bulb lamp with a dispersed phosphor or reflects from surface with deposited phosphor layer.

Usually as yellow orange phosphor one use rather expensive cerium-activated yttrium-aluminate or terbium-aluminate garnets of various compositions under the general formula (Ln)₃Al₅O₁₂ wherein Ln=Y, Tb, Gd, Ce, La, Lu, Pr, abbreviated as (YAG:Ce) or (TAG:Ce), and europium-activated nitride (Ca,Sr,Ba)₂Si₅N₈:Eu²⁺ [C. Ronda Luminescence: From Theory to Application. Science, 2007, 260 p.].

The light efficiency of both light sources is about the same and may be more then 100 lumen/Watts. This value is almost 10 times higher than that of incandescent lamps and 1.5 times higher than that of gas-discharge lamps of the last generation.

At the moment a white LED lamps dominate in the lighting engineering. A level of bulb LED lamps production is rather low. It is quite understandable because of the technology of bulb LED lamps production is more complicated and requires about two times more of expensive yellow-orange phosphor per lumen of radiation.

However the bulb lamps have a number of advantages. The most important one is longer life time caused by lower (<60° C.) working temperature on the phosphor in comparison with quasi-point light modification (up to 120° C.).

For both types of light sources there is the problem of colour rendition correctness when the combination of the blue emission of the light-emitting diode and the yellow-orange luminescence not always corresponds accepted standards of white light.

The authors of a number of patents tried to solve the problem pointed above. It was suggested to use mixtures of yellow-orange phosphors differing from each other in the position of the maximum in the luminescence spectrum. The examples of such mixtures are (YAG)1 and (YAG)2 (U.S. Pat. No. 5,998,925), YAG and TAG (U.S. Pat. No. 6,596,195), YAG and oxynitrides (US Patent Application No. 200902844132] or TAG and oxynitrides (U.S. Pat. No. 6,680,569, U.S. Pat. No. 6,657,379). Some patents used blue-green or red phosphors which added to yellow-orange ones to counterbalance the deficiency of green or red colour in white light (U.S. Pat. No. 6,501,100, Dec. 31, 2002, US Class 257/79 Intern'l Class HO1L 027/15).

This procedure allows to carry on the adjusting the parameters of light emitting systems to the accepted standards for white lights. However this solution was unable to cut the high cost of yellow-orange phosphor composition.

In 2009, American ‘Cree’ Corporation suggested using pairs or groups of a yellow-orange phosphor with green, yellow-green or red phosphors for white LED-lampes (US Patent Application No. 20090095966 (US Class: 257/98; Intern') Class: HO1L 33/00), 16 Apr. 2009). The authors, introducing the basic principles of their patent, wrote in Paragraph 1 of their Claims that each of the phosphors in the mixture must absorb the primary blue illumination of the light-emitting diode (430-480 nm) and transform it radiation with longer wave length. The maxima in the luminescence spectrum of the patented compounds should be located at:

### 1) 560 nm and 570 nm (Paragraph 5, Patent Claims);

### 2) 550 nm and 580 nm (Paragraph 7, Patent Claims);

### 3) (500-560) nm and (570-630) nm (Paragraph 9, Patent Claims).

In the Claims the authors describe the following commonly used basic yellow-orange phosphors of different types:

cerium-activated yttrium-gadolinium garnet (YAG:Ce)−(Y+ΣLn)₃Al₅O₁₂, wherein Ln=Gd, Ce and, together with them, one or several lanthanide group elements;
terbium garnet Tb₃₋ₓLnₓAl₅O₁₂:Ce, wherein Ln=Y, Gd, La, Lu (TAG:CE)
europium-activated nitride phosphors of the following composition: (Ca,Sr,Ba)₂Si₅N₈:Eu²⁺,
And also several compounds with red or green emission, normally added to yellow-orange phosphors. The latter include europium-activated substituted silicates of alkali-earth metals of the following composition: Ba_{1-x-y}SrₓCa_{y}SiO₄:Eu, Ba₂SiO₄: Eu, and also Ba₂(Mg,Zn)Si₂O₇: Eu.

In the group of silicate phosphors there were no one phosphor with decay time more then one second. One can believe that it was because the main goal for authors was the adjusting the parameters of the luminescent system to the white light standard but not the achieving of a new property of phosphor system such as a long afterglow. The authors do not consider also the problem of reducing the cost of phosphor composition.

A similar solution was suggested for garnet-structure phosphors in an OSRAM patent (U.S. Pat. No. 6,504,179, 7 Jan. 2003, US Class 257/88 Intern'l Class H01 L 033/00). The authors have chosen the latter Patent as the prototype for their own invention. The authors of that patent suggested that the deficit of the green component in yellow-orange YAG or TAG can be compensated by doping them with blue-green luminophores (the maximum in the luminescence spectrum at 500-525 nm), in particular chloro-silicate luminophores with the empirical formula Ca_{8-x-y}EuₓMn_{y}Mg(SiO₄)₄Cl₂. As an alternative for chloro-silicates, the authors mention europium-activated strontium aluminate systems of the SrAl₂O₄: Eu²⁺ or Sr₄Al₁₄O₂₅: Eu²⁺. However the patent description contains no examples of their practical use in combined composites.

The practical use of combined compounds that contain chloro-silicates and cerium-activated yttrium-aluminate garnets (YAG) or of mixtures of chloro-silicates and terbium-aluminium garnets (TAG) produced compounds corresponding to the white light standard with colour temperature between 4,000 and 10,000 K. The relative amount of the blue-green luminophore dopant, stated in the patent, was 20 to 50 weight percent. The luminescence spectrum of the mixed composite differed significantly from the spectrum typical of the original yellow-orange luminophore, and it was accompanied by the maximum displacement towards shorter waves by 20-25 nm, while brightness increased by 12%.

However, it has to be emphasised that the patent used by us as the prototype of our own invention contained no reference to light storage phosphors, which also belong to the class of strontium aluminate systems yet characterised by long afterglow—just as no such reference was found in the other patents. The phosphors discussed acquire this property only when activation is carried out by introducing manganese and dysprosium into the crystal simultaneously with europium. This property is amplified in the presence Ce, Nd, Tb, and Pr (U.S. Pat. No. 5,686,022; U.S. Class: 252/301.4R; Intern'l Class:C09K11/02, Nov. 11, 1997), (U.S. Pat. No. 6,190,577 (U.S. Class: 313/468; Intern'l Class:09K/11/77), Feb. 20, 2001), (U.S. Pat. No. 6,267,911; US Class:; Intern'l Class:C), (RF No. 2236434C2 (C 09 K 11/64, 11/77, 11/80, Feb. 12, 2002), (U.S. Pat. No. 754,046 (U.S. Pat. No. 754,046 (U.S. Class: 252/301.16; Intern'l Class:CO9K11/02, Mar. 17, 2009).

Doping strontium aluminates with the above dopants reduces absorption of the primary blue radiation (440-480 nm) and, consequently, reduces luminescence intensity. This factor might explain why there have been no attempts to solve a comprehensive problem: to adjust the parameters of the luminescence system to the white light standard, to reduce the cost of solid white light sources due to the adding of low cost light storage phosphors that can give luminescence system a new quality: long afterglow. This opens the possibility to create two functional bulb LED lamps which can exploit as usual white light sources and as tracers in life-safety systems in the case of emergency situation when energy is switched off.

The present invention aims at broadening the range of composite luminescent materials for bulb white LED lamps with blue (430-470 nm) chips by means using novel composite phosphor materials which have long afterglow, better optical characteristics and lower cost than the commonly used single yellow-orange phosphors.

This aim was achieved by producing a composite luminescent material including at least two phosphors one of which has yellow-orange luminescence in the 560-630 nm range, while the other one, taken in the amount of 10-90%, is light storage phosphor and belongs to the group of aluminates of alkali-earth metals activated with europium that virtually non-excitable with primary radiation of the light-emitting diode.

One of the following compounds can be used as a yellow-orange phosphors:

cerium-activated yttrium-aluminate or terbium-aluminate garnets of different composition but with the following general formula:
(Ln)₃Al₅O₁₂, wherein Ln=Y, Tb, Gd, Ce, La, Lu, Pr, and/or cerium-activated luminophores based on a non-stoichiometric phase with the general formula (Ln)_{3+α}Al₅O_{12+1.5α}, wherein Ln stands for yttrium and one or several elements from the Tb, Gd, Ce, La, Lu, Pr group, while α is a value representing the stoichiometric index increase in comparison with the index of yttrium gadolinium garnet; α varies between 0.033 and 0.5, and/or europium-activated nitride luminophores of (Ca,Sr,Ba)₂Si₅N₈: Eu²⁺ composition.

One or several alkali-earth aluminates, activated with europium and dysprosium in the presence of manganese or of one or several lanthanides of the Ce, Nd, Pr, Tb group with the general formula (Sr²⁺,Ca²⁺, Mg²⁺, Ba²⁺, Zn²⁺)_{1÷4}Al(B,Ga,In)_{2÷14}O_{4÷25}:Eu²⁺ (Ce³⁺,Tb³⁺,Dy³⁺,Nd³⁺,Pr³⁺) were selected as a light storage phosphor, in particular the following compound:

Mg_{1-x-y-z}SrₓEu²⁺_{y}Mn_{z}⁺²(ΣTR)ₚAl_{q}O_{3.99÷4.05}, where (ΣTR)=Dy, Nd, Ce, wherein x=0.8-0.96, y=0.001-0.03, z=0.005-0.010, p=0.01-0.05, 1.99≦q≦2.05 atomic fractions.

The relationship between the masses of the yellow-orange and light storage phosphors in the composite luminescent material is:

yellow-orange luminophore 10-90%
light storage phosphor 10-90%.
The preferred light storage phosphor concentration range is 40-70 mass %.

The above light storage phosphors are weak absorbers of 430-480 nm radiation. They also have practically no luminescence in the green and yellow-orange parts of the spectrum. Luminescence intensity does not exceed 4-6% of the blue light-emitting diode radiation. Consequently, it would seem that light storage phosphors would have no use in white light sources based on blue-emission light-emitting diodes.

However, the experimental studies carried out by the present authors showed that mixing yellow-orange phosphors with light storage phosphors, which seems like adding worthless constituents, helps to correct the illumination engineering properties of white light sources, without sacrificing too much of their brightness, while also giving the luminescent system a long afterglow.

It is a well-known fact that the market value of light storage phosphors is 50-70 dollars per kilo, which is almost two orders of magnitude lower than that cerium activated yttrium-aluminium garnet, terbium garnet or nitride phosphors (2,000-5,000 $/kg). Taking this into consideration makes it obvious that the use of composite luminescent materials ought to result in a considerable cut in costs of using garnet structure phosphors for LED sources of white light.

Thus, correcting lighting engineering properties of yellow-orange luminophores, giving them a new property, long afterglow, and also reducing their cost can be done by forming such a composite material that would contain light storage phosphors and yellow-orange luminophores, such as cerium-activated yttrium aluminate or terbium aluminate garnets of different composition corresponding to the general formula: (Ln)₃Al₅O₁₂, wherein Ln=Y, Tb, Gd, Ce, La, Lu, Pr and/or

cerium-activated luminophores based on a non-stoichiometric phase with the general formula (Ln)_{3+α}Al₅O_{12+1.5α}, wherein Ln represents yttrium and also one or several elements from the Ln=Tb, Gd, Ce, La, Lu, Pr; α is a value that characterizes the increase of the stoichiometric index in comparison with the one known for the yttrium gadolinium garnet (α varies in the 0.33-0.5 range), and/or
europium-activated nitride (Ca,Sr,Ba)₂Si₅N₈:Eu²⁺ materials.

A light-storage phosphors can be represented by aluminates and mixed aluminate-gallates or aluminate-indiates of alkali-earth metals of different composition or related to them alumoborates, activated with Eu²⁺ in the presence of Mn²⁺, and at least one of the lanthanides: Dy³⁺, Nd³⁺, Tb³+, Pr³⁺ with the general formula:

(Ca²⁺, Mg²⁺, Sr²⁺, Ba²⁺, Zn²⁺, Mn²⁺)_{1÷4}Al(B,Ga)_{2÷14}O_{4÷25}:Eu²⁺(Ce³⁺,Tb³⁺,Dy³⁺,Nd³⁺, Pr³⁺).

### PRACTICAL EXAMPLES

The authors carried out a comparative study of the illumination engineering characteristics (brightness, luminescence spectrum, colour coordinates, colour temperature, afterglow time) of commonly used cerium-activated yellow-orange luminophores of garnet structure (Y+ΣLn)₃Al₅O₁₂, wherein Ln=Gd,Tb,Ce, also of a phase of cerium-activated non-stoichiometric yttrium-gadolinium garnet

(Y_{1-x-y}GdₓCeα_{y})₃₊αAl₅O_{12+1.5}, wherein α characterises the increase of the stoichiometric index in comparison with the value for yttrium-gadolinium garnet, varying between 0.033 to 0.5, and of composite luminescent materials produced after yellow-orange luminophores were mixed with one of light storage phosphors with long afterglow, based on a strontium-magnesium aluminate, europium-activated (Eu²⁺) in the presence of Mn²⁺, as well as Dy³⁺, Nd3⁺, and Ce3⁺. Their chemical composition corresponded to the following formulas:

### Sr_{0.96}Mg_{0.02}Mn²⁺_{0.005}Eu²⁺_{0.015} (Dy_{0.017}Nd_{0.008}Ce_{0.003})Al_{2.03}O_{4.044} and

### Sr_{0.93}Mg_{0.04}Mn²⁺_{0.01}Eu²⁺_{0.02} (Dy_{0.025}Nd_{0.010}Ce_{0.005})Al_{2.02}O_{4.04}

Some of the luminophores used were synthesized by the authors, while others were commercially available, manufactured in China.

Luminophores were mixed for 2-3 hours, either dry or in a fluid (hexane, octane, isopropanol) in a ‘drunk barrel’ or in a vibrostand with polyethylene-coated balls. The illumination engineering parameters were measured in a certified installation, using a standard blue light-emitting diode (λₘₐₓ=450 nm). Its radiation passed through a flat layer of an organic matrix with a composite material dispersed in it at 5÷15 mg/cm² of the matrix surface.

In each of the practical examples, properties of the composite materials were compared with the properties of the yellow-orange luminophore used in them, with indices: 1-0; 2-0; 3-0; 4-0;5-0 and 6-0.

### Practical Example 1 (1-0, 1-1, 1-2)

(1-1) 60 g of stoichiometric yttrium-gadolinium garnet of (Y_{0.056}Gd_{0.41}Ce_{0.03})_{3.00}Al₅O₁₂ composition were mixed with 40 g of light storage phosphor of
Sr_{0.96}Mn_{0.02}Mn²⁺_{0.005}Eu²⁺_{0.015} (Dy_{0.017}Nd_{0.008}Ce_{0.003})Al_{2.03}O_{4.044} mixture was homogenised for 2 hours in a polyethylene vessel, using steel balls coated with polyethylene, in a ‘drunk barrel mixer’.
(1-2) 40 g of (Y_{0.56}Gd_{0.41}Ce_{0.03})_{3.00}Al₅O₁₂ yttrium-gadolinium garnet (the same composition as in 1-1) were mixed with 60 g of light storage phosphor,
Sr_{0.96}Mg_{0.02}Mn²⁺_{0.005}Eu²⁺_{0.015} (Dy_{0.017}Nd_{0.008}Ce_{0.003})Al_{2.03}O_{4.044}. Dry homogenisation was carried out for 2 hours in a polyethylene vessel, using polyethylene-coated 10 mm diameter steel balls.

### Example 2 (2-0, 2-1, 2-2)

(2-1) 50 g of stoichiometric yttrium-gadolinium garnet of (Y_{0.847}Gd_{0.129}Ce_{0.024})_{3.00}Al₅O₁₂ composition were mixed with 50 g of light storage phosphor of
Sr_{0.93}Mg_{0.04}Mn²⁺_{0.01}Eu²⁺_{0.02} (Dy_{0.025}Nd_{0.005}Ce_{0.005})Al_{2.02}O_{4.04} composition. The mixture was homogenized for 3 hours in a polyethylene vessel, on a vibrostand, in 100 ml of hexane. To intensify the process, polyethylene-coated 5 mm steel balls were used in a ‘drunk barrel’ mixer. When the mixing was complete, the liquid was filtered off, and the mixture was dried under a water-jet pump at room temperature.
(2-2) 33 g of yttrium-gadolinium garnet of (Y_{0.847}Gd_{0.129}Ce_{0.024})_{3.00}Al₅O₁₂ (the same composition as in (2-1) were mixed with 67 g of light storage phosphor of
(2-3) 33 g of yttrium-gadolinium garnet of (Y_{0.847}Gd_{0.129}Ce_{0.024})_{3.00}Al₅O₁₂ (the same composition as in (2-1) were mixed with 67 g of light storage phosphor of
Sr_{0.93}Mg_{0.04}Mn²⁺_{0.01}Eu²⁺_{0.02} (Dy_{0.025}Nd_{0.010}Ce_{0.005})Al_{2.02}O_{4.04} composition. Homogenization was carried out for 3 hours in a polyethylene vessel, on a vibrostand, in 100 ml of hexane. To intensify the process, polyethylene-coated 5 mm steel balls were used in a ‘drunk barrel’ mixer. When the mixing was complete, the liquid was filtered off, and the mixture was dried under a jet pump at room temperature.

### Example 3

(3-1) 40 g of stoichiometric yttrium-gadolinium garnet of (Y_{0.847}Gd_{0.129}Ce_{0.024})_{3.00}Al₅O₁₂ composition were mixed with 60 g light storage phosphor of
Sr_{0.96}Mg_{0.02}Mn²⁺_{0.005}Eu²⁺_{0.015} (Dy_{0.017}Nd_{0.008}Ce_{0.003})Al_{2.03}O_{4.044} composition. The mixture was homogenised for 2 hours in a polyethylene vessel, on a vibrostand, in 150 ml of isopropyl spirit. To intensify the process, polyethylene-coated 5 mm steel balls were used. When the mixing was complete, the liquid was filtered off, and the mixture was dried under a jet pump at room temperature.
(3-2) 20 g of stoichiometric yttrium-gadolinium garnet of (Y_{0.847}Gd_{0.129}Ce_{0.024})_{3.00}Al₅O₁₂ composition were mixed with 80 g light storage phosphor of
Sr_{0.96}Mg_{0.02}Mn²⁺_{0.005}Eu²⁺_{0.015} (Dy_{0.017}Nd_{0.008}Ce_{0.003})Al_{2.03}O_{4.044} composition. The mixture was homogenised for 2 hours in a polyethylene vessel, on a vibrostand, in 150 ml of isopropyl spirit. To intensify the process, polyethylene-coated 5 mm steel balls were used. When the mixing was complete, the liquid was filtered off, and the mixture was dried under a jet pump at room temperature.

### Example 4 (4-0, 4-1)

(4-1) 50 g of stoichiometric yttrium-terbium-gadolinium garnet of (Tb_{0.60}Y_{0.22}Gd_{0.14}Ce_{0.04})_{3.00}Al₅O₁₂ composition were mixed with 50 g light storage phosphor of
Sr_{0.93}Mg_{0.04}Mn²⁺_{0.01}Eu²⁺_{0.02} (Dy_{0.025}Nd_{0.010}Ce_{0.005})Al_{2.02}O_{4.04}. The dry mixture was homogenised for 3 hours in a polyethylene vessel, using polyethylene-coated steel balls in a ‘drunk barrel’ mixer.

### Example 5 (5-0, 5-1, 5-2)

(5-1) 50 g of non-stoichiometric (Y_{0.555}Gd_{0.40}Ce_{0.045})_{3.50}Al₅O_{12.75} phase were mixed with 50 g of light storage phosphor of
Sr_{0.96}Mg_{0.02}Mn²⁺_{0.005}Eu²⁺_{0.015} (Dy_{0.017}Nd_{0.008}Ce_{0.003})Al_{2.03}O_{4.044} composition. Dry homogenization was carried out for 3 hours in a polyethylene vessel, using polyethylene-coated steel balls in a ‘drunk barrel’ mixer.
(5-2) 33 g of non-stoichiometric (Y_{0.555}Gd_{0.40}Ce_{0.045})_{3.50}Al₅O_{12.75} phase were mixed with 67 g of light storage phosphor of
Sr_{0.96}Mg_{0.02}Mn²⁺_{0.005}Eu²⁺_{0.015} (Dy_{0.017}Nd_{0.008}Ce_{0.003})Al_{2.03}O_{4.044} composition. Dry homogenization was carried out for 3 hours in a polyethylene vessel, using polyethylene-coated steel balls in a ‘drunk barrel’ mixer.

### Example 6 (6-0, 6-1)

50 g of non-stoichiometric (Y_{0.96}Ce_{0.04})_{3.5}Al₅O_{12.75} phase were mixed with 50 g light storage phosphor of Sr_{0.93}Mg_{0.04}Mn²⁺_{0.01}Eu²⁺_{0.02} (Dy_{0.025}Nd_{0.010}Ce_{0.005})Al_{2.02}O_{4.04} composition. The mixture was homogenised for 2 hours in a polyethylene vessel, on a vibrostand, in 150 ml of octane. To intensify the process, polyethylene-coated 5 mm steel balls were used. When the mixing was complete, the liquid was filtered off, and the mixture was dried under a jet pump at room temperature.

Lighting engineering properties of the samples studied are shown in Table 1.

TABLE 1
LIGHTING ENGINEERING PROPERTIES OF COMPOSITE LUMINESCENT
MATERIALS PRODUCED BY MIXING YELLOW-ORANGE PHOSPHORS AND
LIGHT STORAGE PHOSPHORS

| | Chemical composition and mass | | | | | | |
|---|---|---|---|---|---|---|---|
| | fraction of yellow-orange luminophore | | | Colour | | | |
| Sample | in composite luminescent materials | | | coordinates | | λₘₐₓ | |
| No. | Composition | Mass % | I, % | x | y | (nm) | T_{c}, K |
| 1-0 | (Y_{0.56}Gd_{0.41}Ce_{0.03}) | 100 | 100 | 0.447 | 0.413 | 581 | 2920 |
| 1-1 | _{3.00}Al₅O₁₂ | 60 | 98.5 | 0.432 | 0.400 | 580 | 3060 |
| 1-2 | | 40 | 91 | 0.414 | 0.379 | 580 | 3220 |
| 2-0 | (Y_{0.847}Gd_{0.129}Ce_{0.024}) | 100 | 100 | 0.429 | 0.435 | 575 | 3350 |
| 2-1 | _{3.00}Al₅O₁₂ | 50 | 96 | 0.380 | 0.371 | 573 | 3950 |
| 2-2 | | 33 | 85 | 0.353 | 0.337 | 571 | 4600 |
| 3-0 | (Y_{0.847}Gd_{0.129}Ce_{0.024}) | 100 | 100 | 0.429 | 0.435 | 575 | 3350 |
| 3-1 | _{3.00}Al₅O₁₂ | 40 | 90 | 0.369 | 0.366 | 573 | 4250 |
| | | 20 | 75 | 0.321 | 0.298 | 572 | 6100 |
| 4-0 | (Tb_{0.60}Y_{0.22}Gd_{0.14}Ce_{0.04}) | 100 | 100 | 0.441 | 0.482 | 581 | 3515 |
| 4-1 | _{3.00}Al₅O₁₂ | 50 | 90 | 0.360 | 0.365 | 578 | 4710 |
| 5-0 | (Y_{0.555}Gd_{0.40}Ce_{0.045}) | 100 | 100 | 0.464 | 0.454 | 580 | 2960 |
| 5-1 | _{3.50}Al₅O_{12.75} | 50 | 95 | 0.402 | 0.382 | 578 | 3500 |
| 5-3 | | 33 | 93 | 0.340 | 0.300 | 576 | 4900 |
| 6-0 | (Y_{0.96}Ce_{0.04}) _{3.5}Al₅O_{12.75} | 100 | 100% | 0.399 | 0.452 | 564 | 4050 |
| 6-1 | | 60 | 100% | 0.336 | 0.354 | 560 | 5400 |

I % represents relative brightness of luminescence;
x and y are colour coordinates;
λₘₐₓ (nm) indicates the wave length of the maximum in the luminescence spectrum;
T_{c} is correlated colour temperature (K)

Changes caused by light storage phosphors were assessed by comparing the properties of composite materials with those of the light-emitting diode—yellow-orange phosphor system.

It is easy to see that adding even as much as 80 mass % of a light storage phosphor to the yttrium-gadolinium garnet with yellow-orange luminescence results in composite luminescent materials, the brightness of which measures 75% of that of the original yttrium-gadolinium garnet.

These results suggest that the luminescence of light storage phosphors did not contribute significantly to the glow of the yellow-orange phosphor. On the other hand, it was established that, as concentration of a light storage phosphor increased, both the colour coordinates decreased systematically. This permits to adjust the colour coordinates to the accepted white light standards with the correlated colour temperature being from 2,900 to 6,100 K, which corresponds to the transition from the ‘warm’ to the ‘standard’ white light emission (the compositions located near the absolutely black body emission curve are rendered in italics in the Table).

The preferred concentration of light storage phosphors was in the 40-70 mass % range. Lower concentrations resulted in a weaker afterglow, while on the other hand, the brightness of the white light source decreased at higher concentrations of light storage phosphors.

The best composite luminescent materials within the above-discussed concentration range had an afterglow that remained biologically discernable for 8 hours. The brightness of the residual luminescence at the moment the power was switched off was proportional to the concentration of the light storage phosphor, and to the stationary brightness of its luminescence; it also depended on the thickness of the composite luminescent layer in the white light source.

Thus, test results come to the conclusion that in practical applications LED light sources based on novel composite luminescence materials including light storage phosphors can be two functional devices. On the one hand they can be functioned as usual light sources for lighting but at the same time they can be used as tracers in darkness in the case of emergency situation when energy is switched off.

1. A composite luminescent material for solid white light sources, which contains a light-emitting diode radiating in the 430-480 nm range, and a mixture of at least two phosphors, one of which has yellow-orange luminescence in the 560-630 nm range, and the other belonging to the group of europium-activated aluminates of alkali-earth metals, different in that the second phosphor represents at least one light storage phosphor with long afterglow that virtually cannot be excited with the primary radiation of the light-emitting diode, used in the range of 10-90 mass %, while the mass ratio between the yellow-orange and light storage phosphors is:
yellow-orange phosphor 10-90%
light storage phosphor 10-90%.

2. The composite luminescent material according to claim 1, wherein the yellow-orange phosphor has one of the following compositions:
cerium-activated yttrium-aluminate or terbium-aluminate garnets with the general formula: (Ln)₃Al₅O₁₂, wherein Ln=Y, Tb, Gd, Ce, La, Lu, Pr;
cerium-activated phosphor, based on an non-stoichiometric phase with the general formula (Ln)_{3+α}Al₅O_{12+1.5α}, where Ln represents yttrium and one or several elements from the Tb, Gd, Ce, La, Lu, Pr group, α is a value characterising the increment of the stoichiometric index in comparison with the known one for yttrium-gadolinium garnet; α varies within the 0.033-0.5 range, and/or:
europium-activated nitride luminophores of the (Ca,Sr,Ba)₂Si₅N₈: Eu²⁺.

3. The composite luminescent material according to claim 1, which includes either one or several aluminates of alkali-earth metals, activated with europium and dysprosium in the presence of manganese and either one or several lanthanides from the Ce, Nd, Pr, Tb group with the general formula:
(Sr²⁺, Ca²⁺, Mg²⁺, Ba²⁺, Zn²⁺, Mn²⁺)_{1÷4}Al(B,Ga)_{2÷14}O_{4÷25}:Eu²⁺(Ce³⁺,Tb³⁺,Dy³⁺, Nd³⁺, Pr³⁺).

4. The composite luminescent material according to claim 1, characterised in that the following material is used as a light storage phosphor:
Mg_{1-x-y-z}SrₓEu_{y}⁺²Mn_{z}⁺²(ΣTR)ₚAl_{q}O_{3.99÷4.05}, (ΣTR)=Dy, Nd, Ce, wherein x=0.8-0.96, y=0.001-0.03, z=0.005-0.010, p=0.01-0.05, 1.99≦q≦2.05 atomic fractions.

5. The composite luminescent material according to claim 1, characterised in that the preferred light storage phosphor concentration range is 40-70 mass %.
